(19) United States
(12) Patent Application Publication
(10) Pub. No.: US 2025/0374809 A1
(43) Pub. Date: Dec. 4, 2025

(54) DISPLAY DEVICE INCLUDING A FILLING LAYER HAVING FUNCTIONAL PARTICLES

(71) Applicant: SAMSUNG DISPLAY CO., LTD., YONGIN-SI (KR)

(72) Inventors: JIEUN KO, Yongin-si (KR); YOHAN KIM, Yongin-si (KR); WONMIN YUN, Yongin-si (KR); BYOUNG DUK LEE, Yongin-si (KR); SEUNGJU LEE, Yongin-si (KR); HAEMYEONG LEE, Yongin-si (KR); SUMIN JUNG, Yongin-si (KR); HYE-YOUNG HAN, Yongin-si (KR)

(21) Appl. No.: 19/172,109

(22) Filed: Apr. 7, 2025

(30) Foreign Application Priority Data
Jun. 3, 2024 (KR) 10-2024-0072697

(51) Int. Cl. H10K 59/80; H10K 59/38; H10K 102/00

(52) U.S. Cl. CPC H10K 59/877; H10K 59/38; H10K 2102/331

(57) ABSTRACT

A display device includes a display unit including a first substrate and an encapsulation layer disposed on the first substrate, and a color conversion unit disposed on the encapsulation layer, the color conversion unit including a color filter layer, a color conversion layer including quantum dots, and a filling layer including functional particles and disposed between the color conversion layer and the color filter layer, the filling layer including a first region adjacent to the encapsulation layer and a second region disposed above the first region, wherein a concentration of the functional particles included in the first region is different than a concentration of the functional particles included in the second region.

### CROSS-REFERENCE TO RELATED APPLICATION

This application claims priority to and the benefit of Korean Patent Application No. 10-2024-0072697 filed at the Korean Intellectual Property Office on Jun. 3, 2024, the entire contents of which are herein incorporated by reference.

### BACKGROUND

### (a) Technical Field

The present disclosure relates to a display device and a method of manufacturing the same, and more particularly to a display device including a filling layer having functional particles.

### (b) Discussion of Related Art

Typically, a light emitting component is a device that emits light when holes supplied by an anode and electrons supplied by a cathode combine in a light emitting layer formed between the anode and cathode to form excitons, which stabilize and emit light.

Light emitting components may have various characteristics such as wide viewing angle, fast response speed, thinness, and low power consumption. These characteristics have led to the light emitting components being widely applied to various electrical and electronic devices such as televisions, monitors, and mobile phones.

Recently, a display device including a color conversion layer has been proposed to implement a highly efficient display device. The color conversion layer may convert incident light into a different color. For example, the color conversion layer may perform color reproduction by utilizing high-energy blue light to generate red and green light, which may enable broad color representation.

### SUMMARY

Aspects of the present disclosure improve characteristics of the functional particles by mixing functional particles in a filling layer and phase-separating them to provide a double layer of functional particles and polymers, and provide a display device with high light efficiency.

A display device according to an embodiment includes a display unit including a first substrate and an encapsulation layer disposed on the first substrate, and a color conversion unit disposed on the encapsulation layer, the color conversion unit including a color filter layer, a color conversion layer including quantum dots, and a filling layer including functional particles and disposed between the color conversion layer and the color filter layer, the filling layer including a first region adjacent to the encapsulation layer and a second region disposed above the first region, wherein a concentration of the functional particles included in the first region is different than a concentration of the functional particles included in the second region.

The functional particles may include at least one of light scattering particles or high-refractive-index particles.

The functional particles may be in contact with the color filter layer.

The display device may include a second substrate disposed on the encapsulation layer, wherein the color filter layer is disposed between the second substrate and the encapsulation layer, and the filling layer bonds the first substrate and the second substrate.

A display device according to an embodiment comprises a display unit including an encapsulation layer, a partition wall disposed on the encapsulation layer and including a first opening, a second opening, and a third opening, a first color conversion layer disposed within the first opening, a second color conversion layer disposed within the second opening, and a transmission layer disposed within the third opening, and comprising a filling layer including functional particles and disposed on the first color conversion layer, the second color conversion layer, the transmission layer, and the partition wall, wherein the first color conversion layer and the second color conversion layer include quantum dots, and the functional particles include at least one of light scattering particles or high-refractive-index particles.

A second substrate may be disposed on the encapsulation layer, and a color filter may be disposed between the second substrate and the encapsulation layer.

The filling layer may include a first region adjacent to the encapsulation layer and a second region disposed above the first region, and a concentration of the functional particles included in the first region may be greater than a concentration of functional particles included in the second region.

The filling layer may include a first region adjacent to the encapsulation layer and a second region disposed above the first region, and a concentration of the functional particles included in the second region may be greater than a concentration of functional particles included in the first region.

The filling layer may include an initiator, a polymer resin, and the functional particles, and the initiator may account for about 0.01 percentage by weight (wt %) to about 30 wt % of the total weight of the filling layer.

The functional particles may account for 20 wt % to 90 wt % of the total weight of the filling layer.

The functional particles may be inorganic particles or organic particles.

The functional particles include titanium dioxide, alumina, titanium oxide, zirconium oxide, cerium oxide, hafnium oxide, niobium pentoxide, tantalum pentoxide, indium oxide, tin oxide, indium tin oxide, zinc oxide, silicon, zinc sulfur, calcium carbonate, or barium sulfate, and may include at least one of silicon dioxide or magnesium fluoride.

A method of manufacturing a display device according to an embodiment includes forming a light emitting layer on a first substrate, forming an encapsulation layer on the light emitting layer, forming a color conversion layer on the encapsulation layer, and forming a color filter layer on a second substrate, applying a filling material layer on at least one of the first substrate or the second substrate, bonding the first substrate and the second substrate, with the filling material layer disposed between the first substrate and the second substrate, and heat-treating the filling material layer, causing a phase-separation in the filling material layer to form a filling layer disposed between the first substrate and the second substrate, wherein the color conversion layer includes quantum dots.

The filling material layer includes an initiator, a polymer resin, and functional particles, and the functional particles may include at least one of light scattering particles or high-refractive-index particles.

The filling layer includes a first region adjacent to the color conversion layer and a second region disposed above the first region, and the heat-treating causes the functional particles to be phase-separated toward a lower interface of the filling layer, and a concentration of functional particles included in the first region may be greater than a concentration of functional particles included in the second region.

The filling layer includes a first region adjacent to the color conversion layer and a second region disposed above the first region, and the heat-treating causes the functional particles to be phase-separated toward an upper interface of the filling layer, and a concentration of functional particles included in the second region may be greater than a concentration of functional particles included in the first region.

The heat-treating of the filling material layer may be performed at a temperature above the glass transition temperature Tg of the polymer resin and below about 100 degrees Celsius (° C.).

The heat-treating of the filling material layer may be performed within about twenty-four hours of the bonding.

Phase separation may be accelerated by performing a hydrophobic surface treatment or a hydrophilic surface treatment to an interface of the filling material layer.

Phase separation may be accelerated by subjecting the functional particles to a hydrophobic surface treatment or a hydrophilic surface treatment.

According to embodiments, functional particles are mixed in a filling layer and phase-separated, and the functional particles are gathered at the filling layer interface, which may improve the light scattering effect and refraction effect, to provide a display device with improved light efficiency.

### BRIEF DESCRIPTION OF THE DRAWINGS

FIG. 1 is a schematic exploded perspective view of a display device according to an embodiment.

FIG. 2 is a schematic cross-sectional view of a display panel according to an embodiment.

FIG. 3 and FIG. 4 are cross-sectional views of a display panel according to an embodiment.

FIG. 5 and FIG. 6 are cross-sectional views showing a display device with improved light efficiency by introducing a filling layer in which functional particles are phase-separated.

FIG. 7 is a flowchart of a manufacturing process of a display panel according to an embodiment.

FIG. 8 is a block diagram of an electronic device according to an embodiment.

FIG. 9 illustrates schematic diagrams of electronic devices according to various embodiments.

### DETAILED DESCRIPTION

Hereinafter, embodiments of the present disclosure are described in detail with reference to the attached drawings so that those skilled in the art may easily implement the present disclosure. Aspects of the present disclosure may be implemented in many different forms and is not limited to the aspects described herein. Embodiments may be modified in various different ways, all without departing from the spirit or scope of the present disclosure.

In order to clearly explain the present disclosure, parts that may not be relevant to the description may be omitted. Identical or similar components may be given the same reference numerals throughout the specification.

In addition, the size and thickness of each component shown in the drawings may be arbitrarily shown for convenience of explanation, so the present disclosure is not necessarily limited to that which is shown. In the drawings, thicknesses of layers and/or regions may be exaggerated in the drawings to clearly these various layers and regions.

Additionally, when a part of a layer, membrane, region, or plate is said to be “above” or “on” another part, this includes not only cases where it is “directly above” another part, but also cases where there is another part in between. In contrast, when an element is referred to as being “directly on” another element, there are no intervening elements present. In addition, being “above” or “on” a reference part means being disposed above or below the reference part, and does not necessarily mean being disposed “above” or “on” it in the direction opposite to gravity.

In addition, throughout the specification, when a part is said to “include” a certain component, this means that the part may further include other components, but does not exclude other components, unless specifically stated to the contrary.

In addition, throughout the specification, when reference is made to “on a plane,” this means when the target part is viewed from above, and when reference is made to “in a cross-section,” this means when a cross-section of the target portion is cut vertically and viewed from the side.

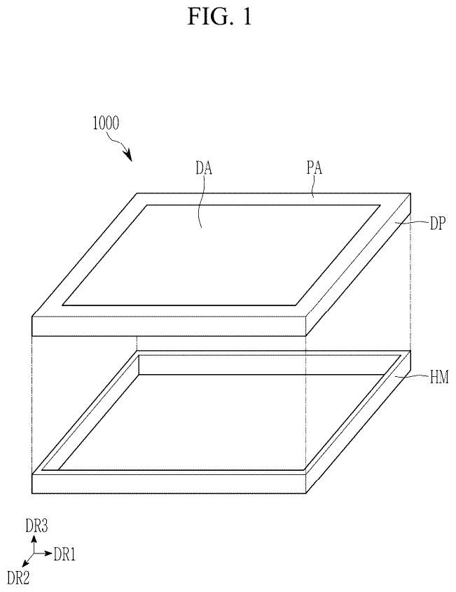

Hereinafter, a display device according to an embodiment will be described with reference to FIG. 1. FIG. 1 is a schematic exploded perspective view of a display device according to an embodiment.

Referring to FIG. 1, a display device 1000 according to an embodiment may include a display panel DP and a housing HM.

The display panel DP may be configured to display an image. The display panel DP according to an embodiment may be made of various other display panels. For example, the display panel DP may include a plurality of sub-display panels. A side of the display panel DP on which the image may be displayed may be parallel to a plane defined by a first direction DR1 and a second direction DR2. A third direction DR3 indicates a normal direction to the plane defined by a first direction DR1 and a second direction DR2, which may be a thickness direction of the display panel DP. The front (or upper) and back (or lower) surfaces of each member may be separated in the third direction DR3. However, the directions indicated by the first to third directions DR1, DR2, and DR3 are relative concepts, and are not intended to be limiting.

The display panel DP may be a flat display panel. The display panel DP may be a rigid display panel or a flexible display panel. The display panel DP may be made of an organic light emitting display panel. However, the type of display panel DP is not limited thereto and may be made of various types of panels. For example, the display panel DP may be made of a liquid crystal display panel, an electrophoretic display panel, or an electrowetting display panel. Additionally, the display panel DP may be made of a next-generation display panel such as a micro-light emitting diode (MicroLED) display panel, a quantum dot light emitting diode display panel, or a quantum dot organic light emitting diode display panel.

MicroLED display panels may include light emitting diodes. The light emitting diodes may measure between about 10 micrometers to about 100 micrometers. Each MicroLED may form a pixel. MicroLED display panels may use inorganic materials. A backlight may be omitted from a MicroLED display panel. The light emitting diodes of a MicroLED may have fast response speed, for example on the order of nano-seconds. The light emitting diodes of a MicroLED may achieve high brightness at relatively low power, for example, about 10% of comparable a liquid crystal display. Further, MicroLED display panels may maintain structural integrity, even when bent.

The quantum dot light-emitting diodes (QD-LEDs) convert electrical energy into light through the recombination of electrons and holes in quantum dots. QD-LEDs display panels may be made by attaching a film containing quantum dots or forming them with a material containing quantum dots. Quantum dots may be particles made of inorganic materials such as indium or cadmium. emit light on their own, and have a diameter of several nanometers or less. By controlling the particle size of quantum dots, light of a desired color may be displayed. QD-LEDs display panels may use blue organic light emitting diodes as light sources. QD-LEDs display panels may generate different colors by attaching a film containing red and green quantum dots over the blue organic light emitting diodes, or by depositing a material containing red and green quantum dots.

As shown in FIG. 1, the display panel DP may include a display region DA where an image may be displayed, and a non-display region PA adjacent to the display region DA. The non-display region (PA) may be a region where images are not displayed. The display region DA may have a rectangular shape, and the non-display region PA may have a shape surrounding at least a portion of the display region DA. However, the shape of the display region DA and the non-display region PA may be designed without being limited thereto.

The housing HM may provide a predetermined internal space. The display panel DP may be mounted on or inside at least a portion of the housing HM. In addition to the display panel DP, various electronic components, such as a power supply unit, a storage device, or an audio input/output module, may be mounted inside the housing HM.

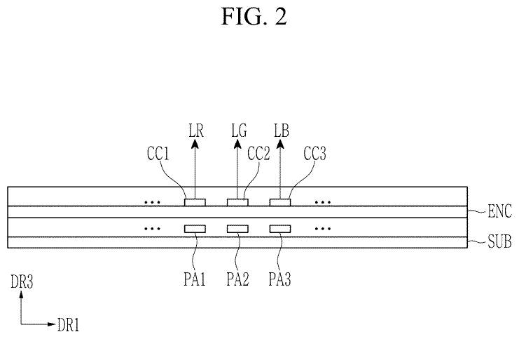

Hereinafter, the display region of the display panel according to an embodiment will be described with reference to FIG. 2. FIG. 2 is a schematic cross-sectional view of a display panel according to an embodiment.

Referring to FIG. 2, a plurality of pixels PA1, PA2, PA3 may be formed on a substrate SUB corresponding to the display region DA of FIG. 1. Each pixel PA1, PA2, PA3 may include a plurality of transistors and a light emitting component connected thereto.

This specification describes an embodiment in which the plurality of pixels PA1, PA2, PA3 are repeatedly arranged in a striped shape, but is not limited thereto. For example, the shape and arrangement of each pixel, and the plurality of pixels, may be modified in various ways.

An encapsulation layer ENC may be disposed on the plurality of pixels PA1, PA2, PA3. The display region DA may be protected by the encapsulation layer ENC. For example, the display region DA may be protected from external air or moisture through the encapsulation layer ENC. The encapsulation layer ENC may be provided to overlap a surface of the display region DA. The encapsulation layer ENC may be integrally provided to overlap an entire surface of the display region DA, and may also be at least partially disposed on the non-display region PA.

A first color conversion unit CC1, a second color conversion unit CC2, and a transmission unit CC3 may be disposed on the encapsulation layer ENC. The first color conversion unit CC1 may overlap the first pixel PA1, the second color conversion unit CC2 may overlap the second pixel PA2, and the transmission unit CC3 may overlap the third pixel PA3.

Light emitted from the first pixel PA1 may pass through the first color conversion unit CC1 and may provide red light LR. Light emitted from the second pixel PA2 may pass through the second color conversion unit CC2 and may provide green light LG. Light emitted from the third pixel PA3 may pass through the transmission part CC3 and may provide blue light LB.

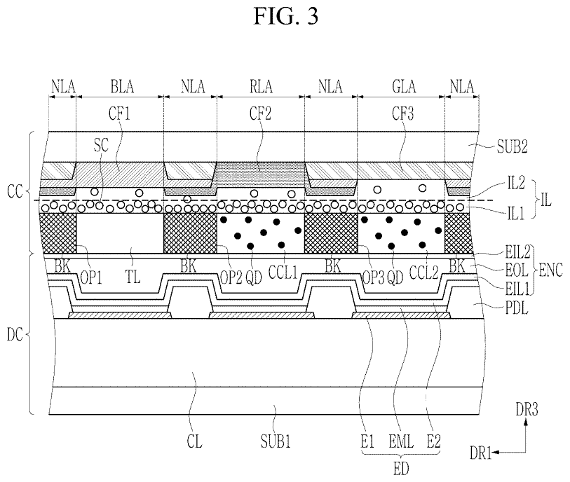

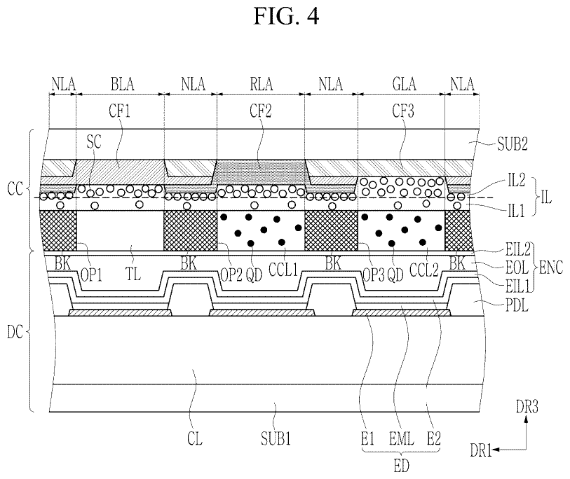

Hereinafter, the structure of the display panel according to an embodiment will be described in more detail with reference to FIG. 3 and FIG. 4. FIG. 3 and FIG. 4 are each cross-sectional views of a display panel according to an embodiment.

Referring to FIG. 3, the display region according to an embodiment may include a red-light emitting area RLA, a green-light emitting area GLA, and a blue-light emitting area BLA. A non-light emitting area NLA may be disposed between adjacent areas. For example, the non-light emitting area NLA may be disposed between the blue-light emitting area BLA and the red-light emitting area RLA, and between the red-light emitting area RLA and the green-light emitting area GLA. Each light emitting region may correspond to a pixel. For example, the blue-light emitting area BLA, the red-light emitting area RLA, and the green-light emitting area GLA may correspond to blue pixels, red pixels, and green pixels, respectively.

Herein, the cross-sectional structure of the display region will be described in more detail. The cross-sectional structure of the display region may include a display unit DC including a light emitting component and a color conversion unit CC in which color conversion particles that convert light provided from the light emitting component into red, green, and blue light may be disposed.

The display unit DC may include a first substrate SUB1. The first substrate SUB1 may include a flexible material such as plastic that may be bent, folded, or rolled.

Within the display unit DC, a circuit layer CL may be disposed on the first substrate SUB1. The circuit layer CL may include driving elements, signal lines, and pads connected to a light emitting element ED.

A pixel defining layer PDL may be disposed on the circuit layer CL. The pixel defining layer PDL may have a pixel opening that may overlap a first electrode E1 and may define a light emitting region. The pixel defining layer PDL may contain an organic material such as polyacrylate resin or polyimide resin, or a silica-based inorganic material. The pixel opening may have a planar shape substantially similar to that of the first electrode E1, and may have a rhomboidal or octagonal shape similar to a rhombus in a plan view, but is not limited thereto and may have any shape such as a square or polygon.

A light emitting component ED may include the first electrode E1, a light emitting layer EML, and the second electrode E2.

The first electrode E1 may be disposed overlapping the pixel opening of the pixel defining layer PDL. The light emitting layer EML disposed on the first electrode E1 may be made of a low-molecular organic material or a high-molecular organic material such as poly(3,4-ethylenedioxythiophene) PEDOT.

The light emitting layer EML may be disposed on the first electrode E1. The light emitting layer EML may be disposed on the first electrode E1 overlapping the pixel opening of the pixel defining layer PDL. Depending on an embodiment, the light emitting layer EML may be disposed on a side or on the pixel defining layer PDL. The light emitting layer EML may be a multilayer structure that may further include one or more of a hole injection layer, a hole transporting layer, an electron transporting layer, or an electron injection layer.

The second electrode E2 may be disposed on the light emitting layer EML. The second electrode E2 may be disposed across a plurality of pixels. The second electrode E2 may receive a common voltage through a common voltage transmitter, which may be disposed in the non-display region.

Here, the first electrode E1 may be an anode, which is a hole injection electrode, and the second electrode E2 may be a cathode, which is an electron injection electrode. However, an embodiment is not necessarily limited thereto, and the first electrode E1 may be a cathode and the second electrode E2 may be an anode depending on the driving method of the organic light emitting display device.

Holes and electrons may be injected into the light emitting layer EML from the first electrode E1 and the second electrode E2, respectively, and light may be emitted when the excitons, formed by the combination of the injected holes and electrons, fall from the excited state to the ground state. Accordingly, the light emitting component ED may provide radiated light toward a transmission layer TL and color conversion layers CCL1 and CCL2 within the display region. Radiated light may include blue light. The radiated light may be blue light alone or may be a mixture of blue light and green light. Alternatively, the radiated light may include all of blue light, green light, and red light.

An encapsulation layer ENC may be disposed on the second electrode E2. The encapsulation layer ENC may comprise a plurality of layers. For example, the encapsulation layer ENC may be formed as a composite film comprising both inorganic and organic layers, the encapsulation layer ENC it may be formed as a structure comprising a first inorganic layer EIL1, an organic layer EOL, and a second inorganic layer EIL2 formed sequentially.

The encapsulation layer ENC may seal the light emitting component, which may be vulnerable to moisture and oxygen, from the top and sides and may block the inflow of external moisture and oxygen.

The color conversion unit CC may be disposed on the encapsulation layer ENC of the display unit DC.

The color conversion unit CC may include a second substrate SUB2. However, the present disclosure is not limited thereto, and the second substrate SUB2 may be omitted. In the case of a display device that does not include the second substrate SUB2, an encapsulation layer ENC covering the top and sides of the color conversion unit CC may be disposed to protect the outer portion of the display device. In the case of a display device includes the second substrate SUB2, the second substrate SUB2 may be disposed overlapping the first substrate SUB1. The second substrate SUB2 may include a flexible material such as plastic that may be bent, folded, or rolled.

The color conversion unit CC may include a partition wall BK disposed on the encapsulation layer ENC. The partition wall BK may include a first opening OP1, a second opening OP2, and a third opening OP3 that may overlap the pixel opening of the pixel defining layer PDL. The sizes of the first opening OP1, the second opening OP2, and the third opening OP3 may be different from each other or the same. Further, the sizes of the first opening OP1, the second opening OP2, and the third opening OP3 may be different or the same as the pixel opening of the pixel defining layer PDL.

The blue-light emitting region BLA and the corresponding transmission layer TL may be disposed in the first opening OP1.

The interior of the transmission layer TL may include a polymer resin. However, in a case that the transmission layer TL does not include quantum dots QD, the blue radiated light may not be converted and may pass through to be incident on the light emitting component ED.

The red-light emitting region RLA and a corresponding first color conversion layer CCL1 may be disposed within the second opening OP2, and the green-light emitting region GLA and a corresponding second color conversion layer CCL2 may be disposed within the third opening OP3.

Each of the first color conversion layer CCL1 and the second color conversion layer CCL2 may include quantum dots QD. Blue radiation light supplied to the first color conversion layer CCL1 may be converted into red light by quantum dots QD, and blue radiation light supplied to the second color conversion layer CCL2 may be converted into green light by quantum dots QD. After blue radiation light is converted by quantum dots QD, red light may be emitted from the first color conversion layer CCL1, and green light may be emitted from the second color conversion layer CCL2.

Quantum dots QD may be selected from group II-VI compounds, group III-V compounds, group IV-VI compounds, group IV elements, or group IV compounds, or combinations thereof.

Group II-VI compounds include binary compounds selected from the group including CdSe, CdTe, ZnS, ZnSe, ZnTe, ZnO, HgS, HgSe, HgTe, MgSe, or MgS, or mixtures thereof, a ternary compound selected from the group including AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, or mixtures thereof, and a monovalent compound selected from the group including HgZnTeS, CdZnSeS, CdZnSeTe, CdZnSTe, CdHgSeS, CdHgSeTe, CdHgSTe, HgZnSeS, HgZnSeTe, or HgZnSTe, or mixtures thereof.

Group III-V compounds include binary compounds selected from the group including GaN, GaP, GaAs, GaSb, AlN, AlP, AlAs, AlSb, InN, InP, InAs, or InSb, or mixtures thereof, a ternary compound selected from the group including GaNP, GaNAs, GaNSb, GaPAs, GaPSb, AlNP, AlNAs, AlNSb, AlPAs, AlPSb, InGaP, InNP, InNAs, InNSb, InPAs, or InPSb, or mixtures thereof, and a monovalent compound selected from the group including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, or mixtures thereof.

Group IV-VI compounds may be selected from a group including binary compounds such as SnS, SnSe, SnTe, PbS, PbSe, or PbTe, or their mixtures, ternary compounds selected from a group including SnSeS, SnSeTe, SnSTe, PbSeS, PbSeTe, PbSTe, SnPbS, SnPbSe, or SnPbTe, or their mixtures, and quaternary compounds selected from a group including SnPbSSe, SnPbSeTe, or SnPbSTe, or mixtures thereof. Group IV elements may be selected from the group including Si or Ge, or mixtures thereof. The group IV compound may be a binary compound selected from the group including SiC or SiGe, or mixtures thereof.

The binary, ternary, or quaternary compounds may exist in the particle at a uniform concentration, or may exist in the same particle with a partially different concentration distribution. Additionally, a first quantum dot QD may have a core/shell structure surrounding a second quantum dot QD. The interface between the core and the shell may have a concentration gradient in which the concentration of elements present in the shell may decrease toward the center. The binary, ternary, or monovalent compounds may be present in the particle at a uniform concentration, or may be present in the same particle with partially different concentration distributions.

The shell may be single layer or multilayer.

The quantum dot QD may have a full width of half maximum (FWHM) of the emission wavelength spectrum of about 45 nm or less, preferably about 40 nm or less, and more preferably about 30 nm or less. Within these ranges, color purity or color reproducibility may be improved. Additionally, since the light emitted through these quantum dots QD may be emitted in all directions, an optical viewing angle may be improved. For example, the optical viewing angle may be increased.

Additionally, the shape of the quantum dots QD is not specifically limited to the shapes commonly used in the field, but more specifically, it may be possible to use spherical, pyramidal, multi-armed, or cubic nanoparticles, nanotubes, nanowires, nanofibers, or nanoplatelets. However, embodiments are not limited thereto.

The quantum dots QD may control the color of light they emit depending on the particle size, and accordingly, the quantum dots QD may have various emission colors such as blue, red, or green.

A ratio of an amount of light absorbed by a quantum dot QD and an amount of light converted to red or green light may be called the color-conversion efficiency. For example, the color-conversion efficiency may be a ratio of the total amount of blue light absorbed by a quantum dot QD to an amount of red light or green light emitted by the quantum dot QD. Display devices with high conversion efficiency may produce vivid colors.

A filling layer IL may be disposed on the partition wall BK, the first color conversion layer CCL1, the second color conversion layer CCL2, and the transmission layer TL. The filling layer IL may provide a display panel by bonding components laminated on the first substrate SUB1 and components laminated on the second substrate SUB2 during the manufacturing process.

The filling layer IL may include an initiator, a polymer resin, and functional particles SC. The filling layer IL may include a first region IL1 adjacent to the color conversion layer CCL and a second region IL2 disposed above the first region IL1. A double layer of polymer and functional particles SC may be formed through phase separation of the functional particles SC included in the filling layer IL.

The functional particles SC may be phase-separated and disposed at a lower part of the filling layer IL, which may be the first region ILL disposed on the partition wall BK, the first color conversion layer CCL1, the second color conversion layer CCL2, and the transmission layer TL. The functional particles SC according to an embodiment may cover the upper surfaces of the partition wall BK, the color conversion layers CCL1, CCL2, and the transmission layer TL.

The concentration of functional particles SC included in the first region IL1 may be greater than the concentration of functional particles SC included in the second region IL2.

A density of the functional particles SC in the filling layer IL may be greater than the density of the polymer resin of the filling layer IL, and the functional particles SC may be concentrated in the lower part of the filling layer IL, which may be the first region IL1. For example, a concentration of the functional particles SC in the first region IL1 may be greater than a concentration of the functional particles SC in the second region IL2.

A hydrophobic treatment may be applied to a lower interface of the filling layer IL and a hydrophobic surface treatment may be applied to the functional particles, or a hydrophilic treatment may be applied to the lower interface of the filling layer IL and a hydrophilic surface treatment may be applied to the functional particles SC, allowing the functional particles SC to be concentrated in the lower part of the filling layer IL, which may be the first region IL1.

The functional particles SC may include at least one of light scattering particles or high-refractive-index particles. The functional particles SC may account for about 20 percentage by weight (wt %) to about 90 wt % of the total weight of the filling layer IL. The functional particles SC may be inorganic particles or inorganic precursors capable of forming highly refractive or light scattering nanoparticles, or may be organic particles.

Light scattering particles may include titanium dioxide, alumina, zirconium oxide, silicon dioxide, or magnesium fluoride, or compounds thereof, but are not limited thereto.

High-refractive-index particles may include titanium dioxide, alumina, titanium oxide, zirconium oxide, cerium oxide, hafnium oxide, niobium pentoxide, tantalum pentoxide, indium oxide, tin oxide, indium tin oxide, zinc oxide, silicon, zinc sulfide, calcium carbonate, barium sulfate, or magnesium oxide, or may also be compounds of these, but are not limited thereto.

The shape of the functional particles SC may be spherical, mesoporous, hollow, or flake shaped, but is not limited thereto.

The initiator of the filling layer IL may be any compound that causes polymerization, such as thermal polymerization, photopolymerization, cationic polymerization, or anionic polymerization. If the concentration of the initiator is high, polymerization may occur quickly, leaving insufficient time for phase separation of the functional particles SC. Therefore, the initiator may account for about 0.01 wt % to about 30 wt % of the total weight of the filling layer. Smaller concentrations of the initiator may be associated with larger phase-separation effects.

Polymer resins of the filling layer IL may be polyacrylate, polyacrylamide, polyacrylic acid, polyvinyl alcohol, polyacrylonitrile, ethylene maleic anhydride, copolymers, cellulose, starch, or cross-linked polyethylene oxide, or their copolymers. However, the polymer resin of the filling layer IL is not limited thereto.

Color filters CF1, CF2, CF3 may be disposed on the filling layer IL. The color filters CF1, CF2, CF3 may form a color filter layer. The color filter layer including the color filters CF1, CF2, CF3 may be disposed below the second substrate SUB2. The first color filter CF1 may overlap the transmission layer TL, the second color filter CF2 may overlap the first color conversion layer CCL1, and the third color filter CF3 may overlap the second color conversion layer CCL2.

The first, second, and third color filters CF1, CF2, CF3 may be made of photosensitive resin and may each contain a dye that exhibits a different color. For example, the first color filter CF1 may pass blue light with a wavelength of about 450 nm to about 495 nm, the second color filter CF2 may pass red light with a wavelength of about 495 nm to about 570 nm, and the third color filter CF3 may pass green light with a wavelength of about 630 nm to about 780 nm. Each color filter may absorb light of wavelengths other than its own, thus, the purity of the blue light emitted outside the display device by the first color filter CF1, the red light emitted outside the display device by the second color filter CF2, and the green light emitted outside the display device by the third color filter CF3 may be increased.

The color filters CF1, CF2, CF3 according to an embodiment may reduce external light reflection of the display device. For example, when external light reaches the first color filter CF1, light within a certain wavelength range may pass through the first color filter CF1, and light of other wavelengths may be absorbed by the first color filter CF1. Accordingly, among the external light incident on the display device, light with a certain wavelength range may pass through the first color filter CF1, and a portion of this light may be reflected by the electrode below it and may be emitted again to the outside. In other words, a portion of the external light incident on the blue-light emitting region BLA may be reflected to the outside, and the blue-light emitting region BLA may play a role in reducing external light reflection. Aspects of the description may also be applied to the second color filter CF2 and the third color filter CF3.

At least two of the first, second, or third color filters CF1, CF2, CF3 may overlap in the non-light emitting region NLA, and may serve as a light blocking member. Therefore, the color filters CF1, CF2, CF3 may prevent or reduce color mixing without a separate light blocking member. However, the structure of an embodiment is not necessarily limited thereto, and the display device may include a separate black matrix layer disposed on the color filters CF1, CF2, CF3.

A separate protective layer may be disposed between the color conversion layers CCL1, CCL2 and the filling layer IL, and between the color filters CF1, CF2, CF3 and the filling layer IL.

The color filters CF1, CF2, CF3 according to an embodiment may have the same or different thicknesses in the third direction DR3. The color filters CF1, CF2, CF3 may have colinear upper surfaces and/or lower surfaces. In a case where the lower surfaces of the color filters CF1, CF2, CF3 have different heights in the third direction DR3, a height of the filling layer IL below the color filters CF1, CF2, CF3 may vary. For example, as shown in FIG. 4, a height of the filling layer IL in the green-light emitting area GLA may be greater than a height of the filling layer IL in the blue-light emitting area BLA or the red-light emitting area RLA.

Hereinafter, a display device according to an embodiment will be described with reference to FIG. 4. Descriptions of components that are the same as those described in FIG. 3 may be omitted.

FIG. 4 is a cross-sectional view of the display device including functional particles SC concentrated at a top portion of the filling layer IL. The amount of functional particles SC included in the second region IL2 may be greater than the amount of functional particles SC included in the first region IL1. At least a portion of the functional particles SC may contact the color filters CF1, CF2, CF3.

When the functional particles SC have a lower density than the polymer resin of the filling layer IL, the functional particles SC may be phase-separated to the top portion of the filling layer IL, as shown in FIG. 4. The functional particles SC phase-separated to the top portion of the filling layer IL may be disposed in contact with the color filters CF1, CF2, CF3. Even if the functional particles SC have a higher density than the polymer resin of the filling layer IL, if the functional particles SC have a hollow structure, the functional particles SC may be concentrated at the top portion of the filling layer IL.

A hydrophobic surface treatment may be applied to an upper interface of the filling layer IL and hydrophobic surface treatment may be applied to the functional particles SC, or a hydrophilic treatment may be applied to a lower interface of the filling layer IL and a hydrophilic surface treatment may be applied to the functional particles SC, allowing the functional particles SC to be concentrated at the top portion of the filling layer IL, which may be the second region IL2.

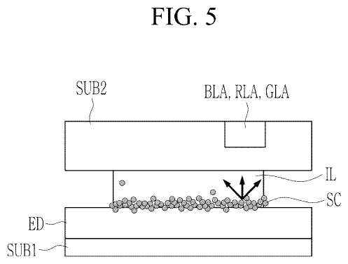

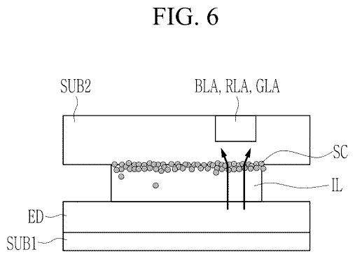

FIG. 5 and FIG. 6 are cross-sectional views showing a display device in which light efficiency may be improved by introducing a filling layer in which functional particles may be phase-separated.

According to FIG. 5, the functional particles SC may be phase-separated toward a lower portion the filling layer IL, so that light may be scattered or the refractive index increased, and a light efficiency of the display device may be increased.

In the display device according to an embodiment, when light scattering particles are used as functional particles SC, the filling layer IL may serve as a filler, a low-refractive layer, and/or a low-refractive capping layer. The functional particles SC may be concentrated at a polymer layer interface of the filling layer IL and light emitting component ED, forming a layer of functional particles. The polymer layer interface of the filling layer IL and light emitting component ED may be referred to as a lower interface of the filling layer IL. The functional particles SC may be concentrated at the lower interface of the filling layer IL, forming a single layer of functional particles. The layer of the functional particles SC may be formed at the lower interface of the filling layer IL and may have unique scattering characteristics, which may improve the scattering effect of the filling layer IL. The functional particles SC concentrated at the interface of the filling layer IL may provide a display device with improved light efficiency by increasing the scattering effect at the lower interface of the filling layer IL.

When high-refractive-index particles are used as functional particles SC, light efficiency may be improved by reducing the refractive index and a mismatch of the lower inorganic layers. The functional particles SC may be concentrated at the interface of the lower interface of the filling layer IL, forming a layer of functional particles. For example, the functional particles SC may be concentrated at the interface of the lower interface of the filling layer IL, forming a single layer of functional particles. High-refractive functional particles SC may be concentrated at the lower interface of the filling layer IL, and may increase the refractive effect. The encapsulation layer may include at least two inorganic layers, and a plurality of inorganic layers may be disposed on the lower part of the display panel. The refractive index of inorganic layers may generally be higher than that of organic layers, and by incorporating high-refractive functional particles SC at the lower interface of the filler layer IL, it may be possible to reduce the refractive index mismatch with the inorganic layer, inhibit or prevent optical loss, and provide a display device with improved optical efficiency.

According to FIG. 6, the functional particles SC are phase-separated toward an upper portion of the filling layer IL, so that light may be scattered or the refractive index increased, and a light efficiency of the display device may be increased.

In the display device according to an embodiment, when light scattering particles are used as functional particles SC, the filling layer IL may serve as a filler, a low-refractive layer, and a low-refractive capping layer. A layer of the functional particles SC may be concentrated at the upper interface of the filling layer IL at the second substrate SUB2, and the scattering effect of the functional particles SC may be improved. Functional particles SC concentrated at the upper interface of the filling layer IL may provide a display device with improved light efficiency by increasing the scattering effect at the upper interface of the filling layer IL.

When using high-refractive-index particles as functional particles SC, light efficiency may be improved by reducing the refractive index and a mismatch of the lower inorganic layers. High-refractive functional particles SC may be formed at the upper interface of the filling layer IL, and a display device may be provided with an improved refractive effect.

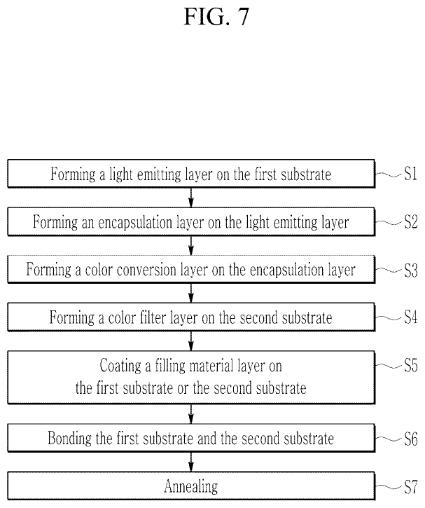

Hereinafter, a method of manufacturing a display panel according to an embodiment will be described in detail with reference to the previously described FIG. 3 and FIG. 4, with reference to FIG. 7. FIG. 7 is a flowchart of a manufacturing process of a display panel according to an embodiment. Descriptions of the same and similar components as the above-described content may be omitted or simplified.

Referring to FIG. 3 and FIG. 4, a circuit layer CL may be formed on the first substrate SUB1. The light emitting layer EML may be formed on the first substrate SUB1 (S1 in FIG. 7).

The encapsulation layer ENC may be formed on the light emitting layer EML (S2 in FIG. 7). The encapsulation layer ENC may include a first inorganic layer EIL1, an organic layer EOL, and a second inorganic layer EIL2, which may be formed sequentially.

Color conversion layers CCL1, CCL2 may be formed on the encapsulation layer ENC (S3 in FIG. 7). A transmission layer TL may also be formed on the encapsulation layer ENC. The color conversion layers CCL1, CCL2 may be formed before or after the transmission layer TL. Processes of forming the color conversion layers CCL1, CCL2 and the transmission layer TL may overlap.

The color filters CF1, CF2, CF3 may be formed on the second substrate SUB2 (S4 in FIG. 7).

A filling material layer may be coated on the first substrate SUB1 and/or the second substrate SUB2 (S5 in FIG. 7). The filling material layer may include an initiator, a polymer resin, and the functional particles SC. The functional particles SC may include at least one of light scattering particles or high-refractive-index particles.

After applying the filling material layer to at least one of the first substrate SUB1 or the second substrate SUB2, the first substrate SUB1 and the second substrate SUB2 may be bonded (S6 in FIG. 7). The first substrate SUB1 and the second substrate SUB2 may be combined, with the filling material layer disposed therebetween, to create a display panel. The bonding step may be performed in a vacuum.

After bonding, the vacuum may be released, and an annealing process for phase separation of the polymer resin and the functional particles SC of the filling material layer may be performed (S7 in FIG. 7). The annealing process may be performed within about twenty-four hours of the coating step or bonding step. For example, the annealing process may be performed at a time before solidification of the filling material layer.

The annealing process may be a heat treatment, and through the heat treatment the polymer resin and functional particles SC of the filling material layer may be phase-separated to form a filling layer. The heat treatment (S7 in FIG. 7) step may be performed at a lower temperature than a temperature of the bonding process (S6 in FIG. 7). For example, the bonding process may be performed below about 100 degrees Celsius (° C.) to protect the light emitting layer EML and color conversion layer CCL containing quantum dots. The heat treatment step for phase separation may be performed at a temperature above the glass transition temperature Tg of the polymer resin and below about 100° C.

When the filling material layer is heated above the glass transition temperature of the polymer resin, the functional particles SC may be phase-separated without being trapped within the filling material layer. Depending on the phase separation conditions, a proportion of particles separated at the interface and a proportion of particles remaining inside the polymer layer of the filling layer IL may be adjusted.

During the heat treatment (S7 in FIG. 7) step, if the density of the functional particles SC is higher than the density of the polymer resin, the functional particles SC may sink to the lower portion of the filling material layer. Depending on the surface energy of the filling material layer, the functional particles SC may sink to the lower portion of the filling material layer. In a case that hydrophobic treatment is applied to the lower interface of the filling material layer and hydrophobic treatment is applied to the functional particles SC, sinking of the functional particles SC to the bottom may be accelerated due to the surface energy. The same concept may apply when hydrophilic treatment is applied to the lower interface of the filling material layer and hydrophilic treatment is applied to the functional particles SC.

The heat treatment (S7 in FIG. 7) step, if the density of functional particles SC is less than that of the polymer resin, the functional particles SC may float to the upper portion of the filling material layer. Depending on the surface energy of the filling material layer, the functional particles SC may float to the upper portion of the filling material layer. When hydrophobic treatment is applied to the upper interface of the filling material layer and hydrophobic treatment is applied to the functional particles SC, the floating of the functional particles SC to the upper portion of the filling material layer may be accelerated due to the surface energy. The same concept may apply when hydrophilic treatment is applied to the upper interface of the filling material layer and hydrophilic treatment is applied to the functional particles SC. In addition, even if the functional particles SC have a higher density than the polymer resin, and if the functional particles SC have a hollow structure, the functional particles SC may phase-separate to the upper portion of the filling material layer and form the filling layer IL.

The filling layer IL may include a first region IL1 adjacent to the color conversion layer CCL and a second region IL2 disposed above the first region IL1. When the functional particles SC phase-separate to the bottom portion of the filling material layer and form a filling layer IL, the concentration of functional particles SC contained in the first region IL1 may be greater than the concentration of functional particles SC contained in the second region IL2. When functional particles SC phase-separate to the upper portion of the filling material layer and form a filling layer IL, the concentration of functional particles contained in the second region IL2 may be greater than the concentration of functional particles SC contained in the first region IL1.

According to a method of manufacturing a display device according to an embodiment, multiple layers may be formed through a single solution process. For example, two layers may be formed in the filling layer IL, which may have different concentrations of functional particles SC. A layer obtained through a single solution process may be the same as forming a single layer of functional particles SC because the functional particles SC may be concentrated at the polymer layer interface. When light scattering particles are used as functional particles SC, the filling layer IL may simultaneously perform the roles of a filler, a low refractive index layer, and a low refractive capping layer, and may allow display devices to be manufactured more economically and efficiently. When high-refractive particles are used as functional particles SC, a display device with improved light efficiency may be provided by inhibiting or preventing light loss by reducing refractive index mismatch with the inorganic layers at the bottom portion of the display panel.

According to an embodiment, in a case where the lower surfaces of the color filters CF1, CF2, CF3 have different heights in the third direction DR3, a height of the filling layer IL below the color filters CF1, CF2, CF3 may vary. In this case, characteristics of the functional particles SC may be tuned for different areas (e.g., the blue-light emitting area BLA, the red-light emitting area RLA, and the green-light emitting area GLA) according to the height of the filling layer IL, where a concentration of the functional particles SC at the upper interface and/or the lower interface may be varied between the areas based on the height of the filling layer IL and a distance that the functional particles SC travel during phase-separation in the different areas.

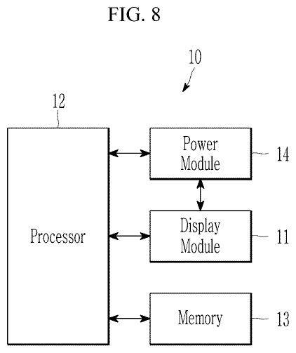

A display device according to an embodiment may be applied to various electronic devices. An electronic device according to an embodiment may include the display device, and may further include modules or devices having additional functions other than the display device. FIG. 8 is a block diagram of an electronic device according to an embodiment. Referring to FIG. 8, the electronic device 10 according to an embodiment may include a display module 11, a processor 12, a memory 13, and a power module 14. The processor 12 may include at least one of a central processing unit (CPU), an application processor (AP), a graphic processing unit (GPU), a communication processor (CP), an image signal processor (ISP), and a controller. The memory 13 may store data information necessary for operations of the processor 12 or the display module 11. When the processor 12 executes an application stored in the memory 13, video data signals and/or input control signals are transmitted to the display module 11, and the display module 11 can process the received signals to output video information through the display screen. The power module 14 may include a power supply module such as a power adapter or battery device, and a power conversion module that converts the power supplied by the power supply module to generate the power necessary for the operation of the electronic device 10. At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

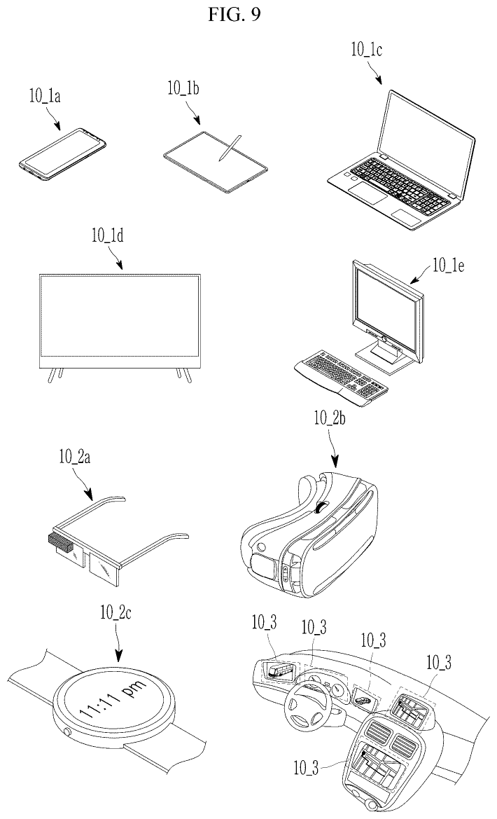

FIG. 9 shows schematic diagrams of electronic devices according to various embodiments. Referring to FIG. 9, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

Although embodiments of the present disclosure have been described in detail above, the scope of the present disclosure is not limited thereto, and various modifications and improvements made by those skilled in the art using the basic concepts of the present disclosure defined in the following claims are also possible.

### DESCRIPTION OF SYMBOLS

DP: display panel
SUB1: first substrate
SUB2: second substrate
CC: color conversion unit
DC: display unit
ENC: encapsulation layer
CCL1, CCL2: color conversion layer
TL: transmission layer
IL: filling layer
IL1: first region
IL2: second region
SC: functional particle
CF1, CF2, CF3: color filter

What is claimed is:

1. A display device, comprising:
a display unit including a first substrate and an encapsulation layer disposed on the first substrate; and
a color conversion unit disposed on the encapsulation layer, the color conversion unit comprising:
a color filter layer;
a color conversion layer including quantum dots; and
a filling layer including functional particles and disposed between the color conversion layer and the color filter layer, the filling layer including a first region adjacent to the encapsulation layer and a second region disposed above the first region,
wherein a concentration of the functional particles included in the first region is different than a concentration of the functional particles included in the second region.

2. The display device of claim 1, wherein the functional particles include at least one of light scattering particles or high-refractive-index particles.

3. The display device of claim 1, wherein the functional particles are in contact with the color filter layer.

4. The display device of claim 1, further comprising a second substrate disposed on the encapsulation layer, wherein the color filter layer is disposed between the second substrate and the encapsulation layer, and the filling layer bonds the first substrate and the second substrate.

5. A display device, comprising:
a display unit including an encapsulation layer;
a partition wall disposed on the encapsulation layer and including a first opening, a second opening, and a third opening;
a first color conversion layer disposed within the first opening;
a second color conversion layer disposed within the second opening;
a transmission layer disposed within the third opening; and
a filling layer including functional particles and disposed on the first color conversion layer, the second color conversion layer, the transmission layer, and the partition wall,
wherein the first color conversion layer and the second color conversion layer include quantum dots, and
the functional particles include at least one of light scattering particles or high-refractive-index particles.

6. The display device of claim 5, further comprising:
a second substrate disposed on the encapsulation layer; and
a color filter disposed between the second substrate and the encapsulation layer.

7. The display device of claim 6, wherein:
the filling layer includes a first region adjacent to the encapsulation layer and a second region disposed above the first region, and
a concentration of the functional particles included in the first region is greater than a concentration of the functional particles included in the second region.

8. The display device of claim 6, wherein:
the filling layer includes a first region adjacent to the encapsulation layer and a second region disposed above the first region, and a concentration of the functional particles included in the second region is greater than a concentration of the functional particles included in the first region.

9. The display device of claim 5, wherein:
the filling layer includes an initiator, a polymer resin, and the functional particles, and the initiator accounts for about 0.01 percentage by weight (wt %) to about 30 wt % of a total weight of the filling layer.

10. The display device of claim 9, wherein:
the functional particles account for about 20 wt % to about 90 wt % of the total weight of the filling layer.

11. The display device of claim 5, wherein:
the functional particles are inorganic particles or organic particles.

12. The display device of claim 5, wherein:
the functional particles include at least one of titanium dioxide, alumina, titanium oxide, zirconium oxide, cerium oxide, hafnium oxide, niobium pentoxide, tantalum pentoxide, indium oxide, tin oxide, indium tin oxide, zinc oxide, silicon, zinc sulfur, calcium carbonate, barium sulfate, silicon dioxide, or magnesium fluoride.

13. An electronic device comprising:
a memory;
a processor to execute an application stored in the memory; and
a display device comprising a display module to output video information provided by the application, wherein:
the display device comprising:
a display unit including a first substrate and an encapsulation layer disposed on the first substrate; and
a color conversion unit disposed on the encapsulation layer, the color conversion unit comprising:
a color filter layer;
a color conversion layer including quantum dots; and
a filling layer including functional particles and disposed between the color conversion layer and the color filter layer, the filling layer including a first region adjacent to the encapsulation layer and a second region disposed above the first region,
wherein a concentration of the functional particles included in the first region is different than a concentration of the functional particles included in the second region.

14. The electronic device of claim 13, wherein the functional particles include at least one of light scattering particles or high-refractive-index particles.

15. The electronic device of claim 13, wherein the functional particles are in contact with the color filter layer.

16. The electronic device of claim 13, further comprising a second substrate disposed on the encapsulation layer, wherein the color filter layer is disposed between the second substrate and the encapsulation layer, and the filling layer bonds the first substrate and the second substrate.

17. The electronic device of claim 13, wherein:
a concentration of the functional particles included in the first region is greater than a concentration of the functional particles included in the second region.

18. The electronic device of claim 13, wherein:
a concentration of the functional particles included in the second region is greater than a concentration of the functional particles included in the first region.

19. The electronic device of claim 13, wherein:
the filling layer includes an initiator, a polymer resin, and the functional particles, and the initiator accounts for about 0.01 percentage by weight (wt %) to about 30 wt % of a total weight of the filling layer.

20. The electronic device of claim 19, wherein:
the functional particles account for about 20 wt % to about 90 wt % of the total weight of the filling layer.
